(19) United States
(12) Patent Application Publication
(10) Pub. No.: US 2003/0185269 A1
(43) Pub. Date: Oct. 2, 2003

(54) Fiber-coupled vertical-cavity surface emitting laser

(76) Inventor: Mikhail A. Gutin, Albany, NY (US)

Correspondence Address: David W. Collins, Intellectual Property Law, Suite 125B, 75 Calle de las Tiendas, Green Valley, AZ, 85614, US

(21) Appl. No.: 10/387,947

(22) Filed: Mar. 13, 2003

Related U.S. Application Data
(60) Provisional application No. 60/368,655, filed on Mar. 26, 2002.
(60) Provisional application No. 60/368,698, filed on Mar. 26, 2002.

(51) Int. Cl. H01S 5/00; H01S 3/08

(52) U.S. Cl. 372/108; 372/50

(57) ABSTRACT

Monolithic structures for coupling either a vertical-cavity surface emitting laser (VCSEL) or a half-cavity vertical cavity surface emitting laser into a single-mode optical fiber are provided. The monolithic structures include a coupler, which comprises a pellet comprising a piece of solid silica glass and a length of graded-index multimode fiber serving as a gradient index lens. Various coupler configurations are provided for handling the cases in which the diameter from the VCSEL is larger or smaller than the diameter of the single-mode fiber. In the case of the half-cavity VCSEL, the single-mode optical fiber including therein an embedded Bragg grating, the Bragg grating reflecting the seed light from the VCSEL, thus providing feedback for laser action. The fiber-coupled laser evidences increased mode field diameter and single-mode operation.

### CROSS-REFERENCE TO RELATED APPLICATIONS

The present application claims priority based on provisional applications Serial No. 60/368,655 and Serial No. 60/368,698, both filed Mar. 26, 2002.

### TECHNICAL FIELD

The present invention relates generally to vertical-cavity surface emitting lasers, and, more particularly, to the use of such lasers in fiber-optic communications.

### BACKGROUND ART

Coupling Single-Mode Vertical Cavity Surface-Emitting Lasers to Optical Fibers

Single-mode vertical cavity surface-emitting lasers (VCSELs) in fiber-optic telecommunications offer the advantage of low-cost light sources capable of providing high modulation rates and long transmission distances. The circular beam shape of the laser makes possible butt coupling into standard single mode fiber (SMF) with high efficiency. When the VCSEL diameter differs from that of the fiber, free-space optical components are typically used for coupling. These solutions require relatively complex fabrication and alignment, and are susceptible to thermal effects, shock and vibration, and other environmental factors. An all-fiber, monolithic device for coupling VCSEL to fiber is therefore of interest.

U.S. Pat. No. 6,014,483 to Thual, et al. entitled “Method of Fabricating a Collective Optical Coupling Device and Device Obtained by Such a Method”, discloses a device for collective optical coupling between a single-mode fiber bundle and an electronic module in the optical telecommunications field which includes joining the single-mode fiber bundle to a graded-index fiber bundle and fracturing the fibers of the graded-index fiber bundle so as to produce graded-index fiber sections in order to form a lens at each end of the single-mode fibers. A commercial product based on the patent is available from Highwave Optical Technologies; see, http://www.highwave-tech.com/products/passivecompo-nents/p7/droite.html. A length of silica is spliced between a single-mode fiber and a graded-index fiber that plays the role of a lens, to provide proper spacing between the single-mode fiber and the lens. The objective of the invention is to “relax tolerances on positioning the fibers along the optical axis and in the plane perpendicular to this axis”. An air gap is implied between the lens and the electronic device, and such a gap is actually shown on the web page depicting the commercial product; see the above-referenced web-site. No monolithic integration between the electronic device and the fiber is described, claimed, or realized in the commercial product.

U.S. Pat. No. 4,701,011 to Emkey, et al. entitled “Multimode Fiber-Lens Optical Coupler” claims an expanded beam coupling arrangement for use in association with single mode fibers. An appropriate length of multimode fiber is fused to the endface of an input single mode fiber, where the length of the multimode fiber is chosen to provide the desired lensing conditions of the input beam. The multimode fiber is thus used as a lens. The multimode fiber-lens connector may be chosen to comprise the same outer diameter as the single mode fiber. Additionally, the use of a section of optical fiber as a lens allows for a fused connection to be used instead of an epoxied connection, which results in a more stable and rugged interface between the fiber and the lens. The device is designed and claimed to couple two single mode fibers, which limits the beam diameters of both the source and the receiver of the optical signal. In addition, the air gap between the parts makes the device susceptible to potential misalignment due to environmental factors.

U.S. Pat. No. 5,940,564 to Jewell entitled “Device for Coupling a Light Source or Receiver to an Optical Waveguide” discloses an improved connector for coupling an optoelectronic transducer to a fiber, comprising an optical relay with two ball lenses. The discrete components of the invention require precise and stable positioning and alignment.

U.S. Pat. No. 5,959,315 to Lebby et al. entitled “Semiconductor to Optical Link” discloses a connector between optical fiber and a semiconductor component. The component and the fiber are brought into a close proximity for butt coupling. Coupling efficiency is likely to be affected by a size mismatch between the semiconductor component and the fiber.

U.S. Pat. No. 5,997,185 to Kropp discloses a laser diode with coupling device. Optical coupling elements in the form of lenses and reflective elements in the form of reflective surfaces are integrated into the coupling device. The transmit module is particularly suitable for vertical cavity surface emitting laser (VCSEL) diodes. The multiple discrete components of the coupling device add complexity and cost to the device and require precise alignment and mechanical stability.

Simple, reliable, monolithic, all-fiber, low-cost fiber-coupled light sources are of interest. In particular, efficient fiber-coupled VCSEL sources have significant commercial potential in many applications, including fiberoptic telecommunications, data communications, and optical interconnects. In addition, an all-fiber monolithic device for coupling beams of different diameters with high efficiency is of practical interest.

B. Large Diameter Single-Mode Vertical Cavity Surface-Emitting Lasers to Optical Fibers

Larger diameter VCSELs are attractive because of higher power at lower current densities and relaxed thermal conditions. In addition, a monolithic fiber-coupled VCSEL is of interest.

While single longitudinal mode operation in VCSEL is usually easily achieved because of the small cavity length, higher transverse modes appear in the laser spectrum when the diameter exceeds a certain value. As a result, the potential bandwidth and transmission distance dramatically decline when the laser is used as the light source in fiber optic telecommunications.

To achieve single transverse mode operation in VCSELs, relatively small apertures are typically introduced in the optical path of VCSELs during fabrication, which limits the optical power of the device.

U.S. Pat. No. 6,263,002 to Hsu, et al. entitled “Tunable Fiber Fabry-Perot Surface-Emitting Lasers” discloses compact, fixed-wavelength and tunable fiber-optic lasers comprising a gain medium within a Fabry-Perot cavity wherein one of the mirrors forming the cavity is a mirror integral with a fiber. One of the possible implementations of the mirror is a fiber Bragg grating. An implementation of the device is also disclosed where intra-cavity length of fiber is introduced, suppressing higher transverse modes, including expanded core fiber that allows for increased mode field diameter in the VCSEL up to 35 μm. Further mode expansion and associated increase in the output power is limited by the achievable mode diameters, energy loss, and mode stability in the expanded core fiber.

U.S. Pat. No. 6,088,376 to O'Brien, et al. entitled “Vertical-Cavity-Surface-Emitting Semiconductor Devices with Fiber-Coupled Optical Cavity” discloses a semiconductor light-emitting device having an optical cavity with a fiber grating. A vertical-cavity-surface-emitting laser can be constructed to produce single-mode tunable laser oscillation and signal wavelength conversion. The laser mode is effectively coupled into a single-mode fiber whose end is in the vicinity of the light-emitting region. This component limits the mode size and the optical power.

U.S. Pat. No. 5,903,590 to Hadley, et al. entitled “Vertical-Cavity Surface-Emitting Laser Device” discloses a vertical-cavity surface-emitting laser. The vertical-cavity surface-emitting laser (VCSEL) device comprises one or more VCSELs with each VCSEL having a mode-control region thereabout, with the mode-control region forming an optical cavity with an effective cavity length different from the effective cavity length within each VCSEL. The transverse mode stability is achieved by containing the laser mode within a predefined size.

U.S. Pat. No. 5,778,018 to Yoshikawa, et al. entitled “VCSELs (Vertical-Cavity Surface Emitting Lasers) and VCSEL-Based Devices” discloses a VCSEL with the cross-sectional dimension of the p-DBR limited to permit only a single fundamental transverse mode in a waveguide composed by the p-DBR (p-side distributed Bragg reflector). Some VCSEL-based devices are developed using arrays of VCSELs in which each VCSEL has a controlled direction of polarization. As in the above references, the VCSEL mode size is contained under a certain value, providing stable single-mode operation but limiting the output power at the same time.

U.S. Pat. No. 5,822,356 to Jewell entitled “Intra-Cavity Lens Structures for Semiconductor Lasers” discloses an improved lens structure that reduces the scattering and/or reflection losses in an optical cavity. The function of the lens in a VCSEL cavity is to reduce the mode size.

U.S. Pat. No. 5,940,422 to Johnson entitled “Laser with an Improved Mode Control” discloses a vertical cavity surface emitting laser with a mode control structure that selectively encourages or inhibits the lasing of the laser in regions of the mode control structure. Light is encouraged to lase and emit light through first portions of the mode control structure while lasing is inhibited in second portions. The first and second portions of the mode control structure are patterned by providing different thicknesses for the first and second portions of the mode control structure. Because the mode control structure is deposited directly on the VCSEL structure, the mode size is relatively small. In addition, due to the design of the mode control structure, coupling of the laser output into a single-mode fiber appears difficult.

Of interest is a single mode VCSEL with large diameter and high output power. Also of interest is a VCSEL with output optical frequency stabilized to one of the channels of a predefined grid, such as the ITU (International Telecommunications Union) grid (a grid of standard optical frequencies defined by ITU for transmission channels in optical telecommunications). A VCSEL tunable over a predefined set of optical frequencies matching the predefined grid is also of interest.

### DISCLOSURE OF INVENTION

In accordance with the present invention, a monolithic structure for coupling a vertical-cavity surface emitting laser into a single-mode optical fiber comprises:

(a) the vertical-cavity surface emitting laser, emitting a beam of light having a first diameter;

(b) the single-mode optical fiber, into which light from the vertical-cavity surface emitting laser is coupled, the single-mode optical fiber having a second diameter;

(c) a pellet comprising a piece of solid silica glass; and

(d) a length of graded-index multimode fiber serving as a gradient index lens.

In the case in which the first diameter exceeds the second diameter, then the monolithic structure comprises, in sequence, the vertical-cavity surface emitting laser, the pellet attached to the vertical-cavity surface emitting layer, the multimode fiber attached to the pellet, and the single-mode optical fiber attached to the multimode fiber. In the case in which the first diameter is smaller than the second diameter, then the monolithic structure comprises, in sequence, the vertical-cavity surface emitting laser, the multimode fiber attached to the vertical-cavity surface emitting laser, the pellet attached to the multimode fiber, and the single-mode optical fiber attached to the pellet.

Also in accordance with the present invention, a fiber optic coupler is provided for coupling light from a vertical-cavity surface emitting laser into a single-mode optical fiber, the vertical-cavity surface emitting laser emitting a beam of light of a first diameter and the single-mode optical fiber having a second diameter. The fiber optic coupler comprises:

(a) a pellet comprising a piece of solid silica glass; and

(b) a length of graded-index multimode fiber serving as a gradient index lens attached thereto.

In the case in which the first diameter exceeds the second diameter, then the fiber optic coupler is attached between the vertical-cavity surface emitting laser and the single-mode optical fiber such that the pellet is attached to the vertical-cavity surface emitting laser and the multimode fiber is attached to the single-mode optical fiber. In the case in which the first diameter is smaller than the second diameter, then the fiber optic coupler is attached between the vertical-cavity surface emitting laser and the single-mode optical fiber such that the multimode fiber is attached to the vertical-cavity surface emitting laser and the pellet is attached to the single-mode optical fiber.

Further in accordance with the present invention, a monolithic structure for transforming and coupling Gaussian beams of arbitrary sizes is provided. A Gaussian beam has a waist, and the monolithic structure is such that when the waist of a Gaussian beam of a predefined size is coincident with an input surface of the structure, then the structure creates a waist of a desired size on an output surface.

Still further in accordance with the present invention, a monolithic, fiber-coupled vertical cavity surface emitting laser is provided. The fiber-coupled laser comprises, in sequence:

(a) a half-cavity vertical cavity surface-emitting laser that emits seed light;

(b) a pellet comprising a piece of solid transparent material secured to the half-cavity vertical cavity surface emitting laser to receive the seed light;

(c) a length of graded-index multimode fiber serving as a gradient index lens secured to the pellet; and

(d) a single-mode optical fiber secured to the multimode fiber, into which seed light from the vertical-cavity surface emitting laser is coupled by the pellet and the graded-index multimode fiber, the single-mode optical fiber including therein an embedded Bragg grating, the Bragg grating reflecting the seed light, thus providing feedback for laser action.

The fiber-coupled vertical cavity surface emitting laser evidences increased mode field diameter and single-mode operation compared with a fiber-coupled laser employing a full-cavity vertical cavity surface emitting laser and no buried Bragg grating.

Other objects, features, and advantages of the present invention will become apparent upon consideration of the following detailed description and accompanying drawings, in which like reference designations represent like features throughout the FIGURES.

### BRIEF DESCRIPTION OF THE DRAWINGS

The drawings referred to in this description should be understood as not being drawn to scale except if specifically noted.

FIG. 1 is a cross-sectional view, depicting the coupling of a vertical-cavity surface emitting laser (VCSEL) to a single-mode fiber for the case when the VCSEL beam diameter exceeds that of the single-mode fiber;

FIG. 2, on coordinates of length (in mm) and beam diameter (in μm) is a plot of the calculated lengths of a piece of solid silica glass (“pellet”) and a multimode fiber (MMF) lens for coupling into a single mode fiber (10.4 μm beam diameter at 1/e²) as a function of the VCSEL beam size;

FIG. 3 is a view similar to that of FIG. 1, but for the case when the VCSEL beam diameter is smaller than that of the single-mode fiber; and

FIG. 4 is a cross-sectional view, depicting the coupling of a vertical-cavity surface emitting laser (VCSEL) fiber Bragg grating (FBG) reflector and large mode field diameter.

### BEST MODES FOR CARRYING OUT THE INVENTION

Reference is now made in detail to a specific embodiment of the present invention, which illustrates the best mode presently contemplated by the inventor for practicing the invention. Alternative embodiments are also briefly described as applicable.

Coupling Single-Mode Vertical Cavity Surface-Emitting Lasers to Optical Fibers

A fiber-coupled vertical cavity surface-emitting laser (VCSEL) assembly 10 is provided comprising a VCSEL chip 12, a piece of solid silica glass (“pellet”) 14, a length of a graded-index multimode fiber (MMF) 16 serving as a gradient index lens (MMF lens), and a single-mode fiber (SMF) 24 receiving the optical signal from the VCSEL. The coupler portion 10a of the assembly 10 comprises the pellet 14 and the multi-mode fiber lens 16. The approach disclosed and claimed herein is universal and is applicable to coupling two different Gaussian beams (modes) 22 of different waist sizes 22a, 22b using the proposed monolithic, all-fiber device 10.

The first (preferred) embodiment is shown in FIG. 1. The assembly 10 comprises the VCSEL 12 attached to one end 14a of the pellet 14 by any conventional means. The other end 14b of the pellet 14 is attached, preferably fusion spliced, to one end 16a of a length of the gradient-index multi-mode fiber lens 16. The gradient-index multi-mode fiber 16 comprises a core 18 and a cladding 20. The lens 16 is attached (preferably, fusion spliced) at its other end 16b to the single mode fiber (SMF) 24 that receives the optical signal from the VCSEL 12. The single mode fiber 24 comprises a core 26 and a cladding 28. The cores 18 of the lens 16 and the core 28 of the single mode fiber 24 are aligned.

In the first embodiment, the size of the Gaussian beam 22 of the VCSEL 12 is larger than the mode size of the single-mode fiber 24. The sizes of the VCSEL 12 that can be coupled to the single-mode fiber 24 in this arrangement range from mode size of the single-mode fiber to the maximum beam size in the multi-mode fiber lens 16. The latter is the size of the beam that would be emitted from the end of a ¼ pitch multi-mode fiber 16 if it were illuminated from the single-mode fiber 24 serving as the light source. This maximum beam size is defined by the properties of the multi-mode fiber lens 16, specifically, by the radial profile of the refractive index, or the numerical aperture (NA) of the multi-mode fiber. For lower values of the numerical aperture, the diameter of the Gaussian beam 22 in the multi-mode fiber lens 16 is larger, which widens the range of possible sizes of the VCSEL 12; however, more light energy from the “wings” of the Gaussian beam 22 is lost in the cladding 20. A larger numerical aperture of the multi-mode fiber 16, accordingly, reduces the losses in the cladding 20 but makes the maximum beam size in the multi-mode fiber smaller and thus reduces the largest size of the VCSEL 12 that can be coupled into the single-mode fiber 24. Note that the “used” portion of the numerical aperture of the multi-mode fiber 16 is equal to numerical aperture of the single-mode fiber 24.

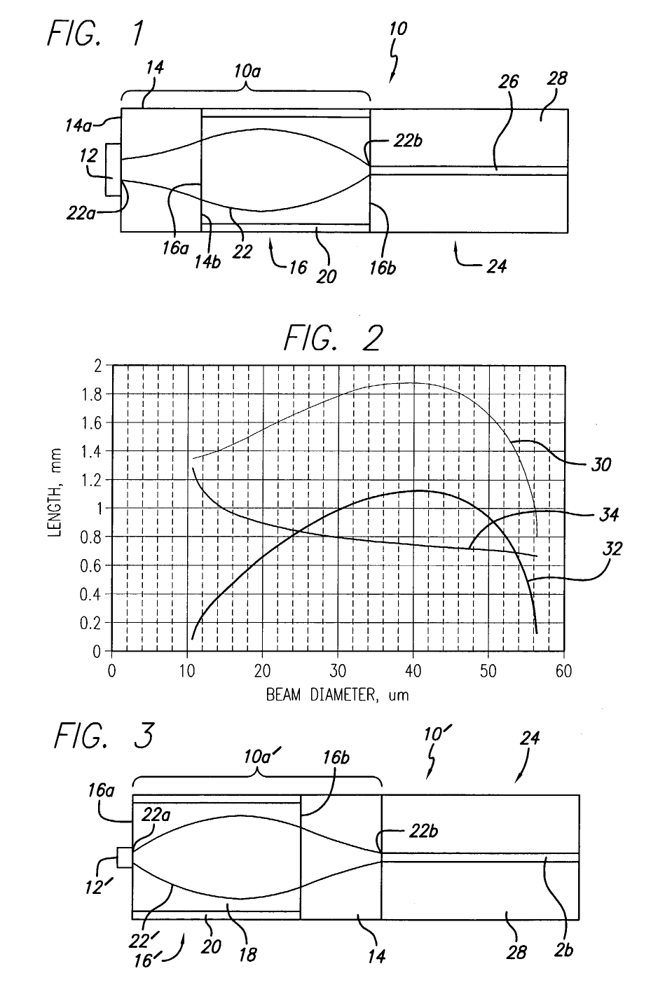

The calculation results of the pellet 14 and lens 16 lengths providing efficient coupling are presented in FIG. 2. The two lengths 14, 16 and the total length of the coupler 10a are plotted as a function of the VCSEL beam diameter at 1/e², where Curve 26 is the length of the pellet 14, Curve 28 is the length of the lens 16, and Curve 30 is the total length of the coupler 10a. The multi-mode fiber lens 16 assumed for the calculation had the refractive index profile

n=n₀−n₂·r² (1)

where r is the radial coordinate, n₀=1.47, and n₂=3.84 mm⁻².

As can be seen from FIG. 2, the multi-mode fiber lens 16 with the index profile described by Eqn. (1) can couple to a standard single mode fiber 24 a number of VCSELs 12 with beam sizes ranging from 10.4 μm to approximately 57 μm. Any VCSEL size in this range can be accommodated by proper selection of two lengths: those of the pellet 14 and the lens 16.

In the case where the VCSEL 12′ has a mode diameter smaller than that of the single-mode fiber 24, then a second embodiment of the coupler 10a′ may be used, shown in FIG. 3. In this case, the assembly 10′ comprises the VCSEL 12′ attached to one end 16a of the multi-mode fiber lens 16 by any conventional means. The other end 16b of the lens 16 is attached, preferably fusion spliced, to the pellet 14. The pellet 14 is attached (preferably, fusion spliced) to the single mode fiber (SMF) 24 that receives the optical signal from the VCSEL 12′.

The structure of the coupler 10a′ differs from the first embodiment by the reversed positions of the pellet 14 and the multi-mode fiber lens 16. As a general rule, the lens 16 is adjacent the VCSEL 12′ with the smaller Gaussian beam 22′ size, whereas the pellet 14 is adjacent the VCSEL 12 with the larger Gaussian beam 22 size.

The numerical aperture of the multi-mode fiber lens 16 will limit the minimum beam size of the VCSEL 12′ in the second embodiment. For smaller diameters of the VCSEL 12′, the beam divergence is higher, and the “used portion” of the numerical aperture of the multi-mode fiber 16 is larger. As the beam divergence increases, the maximum beam diameter in the multi-mode fiber 16 increases also, and a larger portion of the Gaussian beam 20′ reaches the cladding 20, inducing higher energy loss. This defines a limitation on the smallest beam diameter that can be coupled into the single mode fiber 24 of a given numerical aperture with high efficiency.

It is understood that the pellet 14 can be removed and free-space light propagation can be used instead. The pellet 14 offers the advantage of monolithic structure and makes easier design and fabrication of proper coating (index matching between VCSEL 12 and pellet 14, FIG. 1) to prevent reflection of light.

Note that, although coupling of a VCSEL 12 to a single mode fiber 24 is discussed herein, the results are applicable to efficient coupling of any two Gaussian beams (modes), and the combination of the pellet 14 and the lens 16 is a universal device in this sense.

It is understood that, although coupling to a VCSEL 12, 12′ was discussed in detail, the same method and device can be applied for coupling to fiber any other opto-electronic or electro-optical device, including photo detectors.

It will be seen from FIGS. 1 and 3 that a monolithic structure is broadly shown for transforming and coupling Gaussian beams 22, 22′ of arbitrary sizes. The structure is such that when the waist 22a of a Gaussian beam of a predefined size is coincident with one of the surfaces of the structure (input surface), the structure creates a waist 22b of a desired size on its other, output, surface. Whatever the input and output waist 22a, 22b sizes (within a certain range), one can prescribe the lengths, and lengths only, of the pellet 14 and the graded-index fiber (lens) 16 to accommodate for the two waist sizes. There is no need in changing the refractive index profile of the lens 16. The assembly 10, 10′ can be used for transformation of Gaussian beams, including, but not limited to, fiber coupling, and fiber coupling of VCSELs in particular.

Large Diameter Single-Mode Vertical Cavity Surface-Emitting Lasers to Optical Fibers

Device Structure

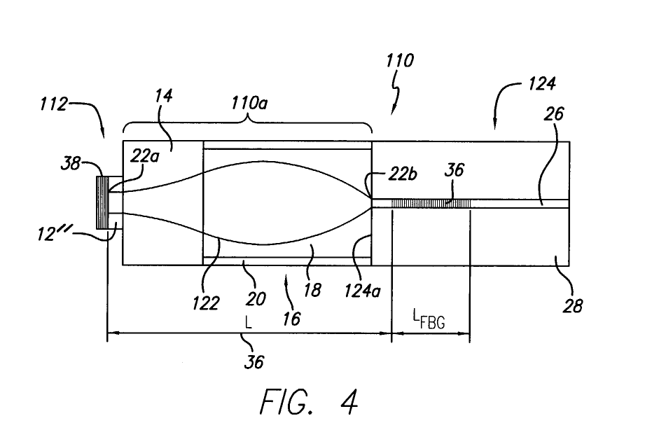

In accordance with another embodiment of the present invention, an assembly 110 comprises a fiber-coupled VCSEL 112, comprising a modified VCSEL (half-cavity VCSEL 12′), a piece of solid silica glass, or pellet, 14, a length of a graded-index multimode fiber 16 serving as a gradient index lens (MMF lens), and a single-mode fiber (SMF) 124 with embedded fiber Bragg grating (FBG) 32, as shown in FIG. 4. The lens 16 has a core 18 and cladding 20 as above, and the single-mode fiber 124 has a core 26 and a cladding 28 as above, except that the Bragg grating 32 constitutes a portion of the core 26.

The half-cavity VCSEL 112 comprises one (“bottom”) highly reflecting mirror 34 and a gain medium 12″. A second mirror, typically included in a conventional VCSEL, is not present in the structure depicted in FIG. 4. The laser cavity 36 is therefore formed by the mirror 34 of the VCSEL 112 and the FBG 32. The gain media 12′, the pellet 14, the multi-mode fiber lens 16, and a portion of the single-mode fiber 124 preceding the FBG 32 are contained inside the cavity 36, denoted “L”. The portion of the single-mode fiber 124 external to the cavity 36 (right of FBG 32 in FIG. 4 and denoted “LFBG”) may be pigtailed or spliced to a transmission fiber (not shown). The resulting device is monolithic, all-fiber, and can be coupled to a transmission single mode fiber by splicing using conventional means.

Mode Field Diameter

The overall length L of the cavity 36 can typically be hundreds of microns to millimeters. This length L, combined with intra-cavity fiber coupling, provides suppression of high transverse modes. Due to expansion in the multi-mode fiber lens 16 and the pellet 14, the mode size in the active media 12″ can be larger that in the prior art; therefore, higher power single mode operation can be expected. Selection of a single longitudinal mode will be provided by the FBG 32, as will be further detailed.

The lengths of the pellet 14 and multi-mode fiber lens 16 will define the mode field diameter in the VCSEL 112 and can be found from the condition for coupling the mode present in the active. media (VCSEL) to the SMF mode. The efficient coupling is achieved when the mode of the Gaussian beam 122 has its waists 22a, 22b on both the VCSEL mirror 34 and at the end 124a of the single-mode fiber 124, respectively. The pellet 14 and the multi-mode fiber lens 16 lengths can be found by solving the equations for Gaussian beam propagation from waist 22a to waist 22b.

The calculation results of the pellet 14 and the lens 16 lengths are the same as presented in FIG. 2, discussed above. The two lengths 14, 16 and the total length of the coupler 110a are plotted as a function of the VCSEL mode field diameter at 1/e². The multi-mode fiber lens 16 assumed for the calculation had the refractive index profile shown in Eqn. (1) above.

As can be seen from FIG. 2, the multi-mode fiber lens 16 with the index profile described by Eqn. (1) can provide VCSEL mode field diameters ranging from 10.4 μm to approximately 57 μm, as above.

It will be noted that, although coupling of a VCSEL 112 to a single mode fiber 118 is discussed herein, the results are applicable to efficient coupling of any two Gaussian beams (modes), and the combination of the pellet 14 and the lens 16 is a universal device in this sense.

The Gaussian mode size of the VCSEL 112 is larger than the mode size of the single-mode fiber 124. The mode sizes of the VCSEL 112 that can be coupled to the single-mode fiber 124 range from the mode size of the single-mode fiber to the maximum beam size in the multi-mode fiber lens 16. Larger mode sizes of the VCSEL 112 are of interest because higher laser power can be expected in this case. The largest possible mode diameter defined by the multi-mode fiber lens 16 is a function of the multi-mode fiber refractive index profile, or numerical aperture (NA). This diameter is the same as the beam diameter at the end of a ¼ pitch multi-mode fiber 16 if it were illuminated from the single-mode fiber 124 serving as the light source. The lower the numerical aperture, the larger the diameter of the Gaussian beam 122 is in the multi-mode fiber lens 16, which widens the range of the mode field diameters of the VCSEL 112; however, more light energy from the “wings” of the Gaussian mode is lost in the cladding 20. A larger numerical aperture of the multi-mode fiber 16, accordingly, reduces the losses in the cladding 20 but also limits the maximum mode field diameter in the VCSEL 112. Note that the “used” portion of the numerical aperture of the multi-mode fiber 16 is equal to the numerical aperture of the single-mode fiber 124.

ITU (International Telecommunications Union) Grid

The cavity length L can be chosen to provide the separation between longitudinal modes matching a predefined grid of optical frequencies, such as the conventional ITU grid. For example, if the optical path length L of the cavity 36 is 1.5 mm, then the longitudinal modes will be spaced at 100 GHz. A 3 mm optical path length L of the cavity 36 will provide a 50 GHz longitudinal mode spacing.

FBG Selectivity

The length L_{FBG}, or the number of periods, of the FBG 32 defines its selectivity. According to the Rayleigh criterion, the spectral range of reflection by the FBG 32 is

Δλ=λ/N (2)

where N is the number of periods in the grating and λ is the central wavelength.

If the reflection range is comparable to or smaller than the mode spacing, then single longitudinal mode operation of the laser 112 will take place. At the central wavelength of 1550 nm and 50 GHz reflection range of the FBG 32, the approximate number of FBG periods required is 3900, corresponding to the FBG physical length L_{FBG} of about 2 mm.

Laser Tuning

If the period of the FBG 32 is changed, e.g., by applied mechanical stress, temperature, or electro-optic effect, then the FBG central wavelength will vary accordingly. The laser optical frequency will be defined by the central wavelength of the FBG 32 and by the longitudinal modes of the cavity 36, defined in turn by the cavity length L. If the longitudinal modes match the ITU grid, as discussed above, then the laser tuning, controlled by the period of the FBG 32, will be in the form of switching from one ITU channel to the next one and so on. The tuning range will be limited by the spectral range where the gain in the active media 12″ exceeds the overall losses in the cavity 36.

It is understood that the FBG 32 is only one possible implementation of the mirror. Other types of mirrors can be applied. The advantage of the FBG 32 is its capability to provide single longitudinal mode operation. Other means, e.g., fiber Fabry-Perot interferometers, can be used for the same purpose.

### Industrial Applicability

The monolithic structure and coupler and the VCSEL with intra-cavity fiber coupling and increased mode field diameter are expected to find use in coupling, e.g., VCSELs and optical fibers together.

Thus, there have been disclosed a fiber optic coupler for coupling a vertical-cavity surface emitting laser to a single-mode fiber in a monolithic structure and a VCSEL with intra-cavity fiber coupling and increased mode field diameter. It will be readily apparent to those skilled in this art that various changes and modifications of an obvious nature may be made, and all such changes and modifications are considered to fall within the scope of the present invention, as defined by the appended claims.

What is claimed is:

1. A monolithic structure for coupling a vertical-cavity surface emitting laser into a single-mode optical fiber comprising:
(a) said vertical-cavity surface emitting laser, emitting a beam of light having a first diameter;
(b) said single-mode optical fiber, into which light from said vertical-cavity surface emitting laser is coupled, said single-mode optical fiber having a core with a second diameter;
(c) a pellet comprising a piece of solid silica glass; and
(d) a length of graded-index multimode fiber serving as a gradient index lens,
wherein in the case in which said first diameter exceeds said second diameter, then said monolithic structure comprises, in sequence, said vertical-cavity surface emitting laser, said pellet attached to said vertical-cavity surface emitting laser, said multimode fiber attached to said pellet, and said single-mode optical fiber attached to said multimode fiber and wherein in the case in which said first diameter is smaller than said second diameter, then said monolithic structure comprises, in sequence, said vertical-cavity surface emitting laser, said multimode fiber attached to said vertical-cavity surface emitting laser, said pellet attached to said multimode fiber, and said single-mode optical fiber attached to said pellet.

2. The monolithic structure of claim 1 wherein said vertical-cavity surface emitting laser is attached to said pellet or said multimode fiber by any conventional means.

3. The monolithic structure of claim 1 wherein said pellet is fusion spliced to said multimode fiber and said multimode fiber is fusion spliced to said single mode fiber, or said multimode fiber is fusion spliced to said pellet and said pellet is fusion spliced to said single mode fiber.

4. The monolithic structure of claim 1 wherein said pellet and said graded-index multimode fiber have a combined calculated length in the range of 1.38 to 1.85 millimeters and couple said beam of light from said vertical-cavity surface emitting laser, having said first diameter of said beam in the range of 10.4 micrometers to 57 micrometers, into said single mode fiber having said core diameter of about 10.4 micrometers.

5. A fiber optic coupler for coupling light from a vertical-cavity surface emitting laser into a single-mode optical fiber, said vertical-cavity surface emitting laser emitting a beam of light of a first diameter and said single-mode optical fiber having a core with a second diameter, said fiber optic coupler comprising:
(a) a pellet comprising a piece of solid silica glass; and
(b) a length of graded-index multimode fiber serving as a gradient index lens attached thereto,
wherein in the case in which said first diameter exceeds said second diameter, then said fiber optic coupler is attached between said vertical-cavity surface emitting laser and said single-mode optical fiber such that said pellet is attached to said vertical-cavity surface emitting laser and said multimode fiber is attached to said single-mode optical fiber and wherein in the case in which said first diameter is smaller than said second diameter, then said fiber optic coupler is attached between said vertical-cavity surface emitting laser and said single-mode optical fiber such that said multimode fiber is attached to said vertical-cavity surface emitting laser and said pellet is attached to said single-mode optical fiber.

6. A monolithic structure for transforming and coupling Gaussian beams of arbitrary sizes, said Gaussian beams each having a waist, said structure is such that when said waist of a said Gaussian beam of a predefined size is coincident with an input surface of said structure, then said structure creates a waist of a desired size on an output surface.

7. The monolithic structure of claim 6 further comprising a first end that is attached to an optoelectronic or electro-optical device by any conventional means and a second end that is attached or fusion spliced to the core of a single mode fiber.

8. A monolithic, fiber-coupled vertical cavity surface emitting laser comprising, in sequence:
(a) a half-cavity vertical cavity surface-emitting laser that emits seed light;
(b) a pellet comprising a piece of solid transparent material secured to said half-cavity vertical cavity surface emitting laser to receive said seed light;
(c) a length of graded-index multimode fiber serving as a gradient index lens secured to said pellet; and
(d) a single-mode optical fiber secured to said multimode fiber, into which seed light from said vertical-cavity surface emitting laser is coupled by said pellet and said graded-index multimode fiber, said single-mode optical fiber including therein an embedded Bragg grating, said Bragg grating reflecting said seed light, thus providing feedback for laser action,
said fiber-coupled vertical cavity surface emitting laser evidencing increased mode field diameter and single mode operation.

9. The monolithic structure of claim 8 wherein said vertical-cavity surface emitting laser is attached to said pellet or said multimode fiber by any conventional means.

10. The monolithic structure of claim 8 wherein said pellet is fusion spliced to said multimode fiber and said multimode fiber is fusion spliced to said single mode fiber.

11. The monolithic structure of claim 8 wherein said pellet and said graded-index multimode fiber have a combined calculated length in the range of 1.38 to 1.85 millimeters and couple said beam of light from said vertical-cavity surface emitting laser, having said first diameter of said beam in the range of 10.4 micrometers to 57 micrometers, into said single mode fiber having said core diameter of about 10.4 micrometers.
